(19) United States
(12) Patent Application Publication
(10) Pub. No.: US 2026/0225875 A1
(43) Pub. Date: Aug. 6, 2026

(54) METHODS OF FORMING DISAGGREGATED SILICON PACKAGES WITH DIRECT RDL-LESS BLOCK ASSEMBLY

(71) Applicant: Intel Corporation, Santa Clara, CA (US)

(72) Inventors: Carlton Hanna, San Jose, CA (US); Richard Geiger, Muenchen (DE); Sidharthi Palanisamy, Taufkirchen (DE); Klaus Herold, Muenchen (DE); Johannes Rauh, Kirchseeon (DE); Tim Helmut Krebs, Munich (DE); Michael Langenbuch, Munich (DE); Thomas Wagner, Regelsbach (DE)

(73) Assignee: Intel Corporation, Santa Clara, CA (US)

(21) Appl. No.: 19/045,462

(22) Filed: Feb. 4, 2025

(51) Int. Cl. B81B 7/00

(52) U.S. Cl. CPC B81B 7/007; B81B 2207/096

(57) ABSTRACT

Microelectronic integrated circuit package structures include a package structure comprising two or more first integrated circuit (IC) dies directly on and electrically coupled to a substrate. A bridge die is adjacent to the two or more first IC dies and directly on the substrate. A second IC die is directly on the bridge die and on at least one of the two or more first IC dies, and a third IC die is directly on the bridge die, adjacent to the second IC die. A mold material at least partially surrounds the two or more first IC dies and the second and third IC dies.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

In many cases, 2.5-3D packaging architectures require a silicon interposer, a redistribution layer (RDL) interposer or a mixed interposer that covers a full area of a package substrate having combined discrete silicon dies and/or chiplets. The use of an RDL or an interposer can limit device performance and add cost.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a cross-sectional view of a disaggregated package structure, in accordance with some embodiments.

FIG. 1B is a top view of a disaggregated package structure, in accordance with some embodiments.

FIGS. 2A-2E are cross-sectional views of methods of forming a disaggregated package structure, in accordance with some embodiments.

FIG. 3 is a cross-sectional view of an IC package structure comprising disaggregated package structure, in accordance with some embodiments.

FIG. 4 illustrates a flow chart of processes for the fabrication of disaggregated package structure, in accordance with some embodiments.

FIG. 5 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with manufacturing 2.5D-3D packages where large portions of a redistribution layer (RDL) or an interposer remain unused. This inefficient use of large portions of the interposer area/module area increases cost and unnecessary processing time. The embodiments herein provide a disaggregated package structure having an intermediate layer of IC dies that are directly attached to top silicon chiplets. The embodiments herein prevent the need for wafer level processing of silicon back end of line (BEOL) or RDL in areas where it is not used and provides opportunity to add function specific IC dies vertically only where needed. Blocks of different process flows such as BEOL, RDL, metal block IC or through mold via IC dies will appear adjacent to each other in the intermediate layer between top silicon dies and a substrate.

The embodiments described herein enable disaggregated silicon chiplet assembly through direct attachment of different functional blocks (ICs) in a chips-first wafer or panel-level process flow without any BEOL or RDL processing on a reconstituted wafer. The embodiments describe a chip-first process where a first layer of IC dies and adjacent dummy dies are initially attached onto a wafer (or panel) carrier to create a reconstituted wafer (or panel). A second layer of IC dies are then attached to the top sides of the first layer of IC dies. The second layer of IC dies each have identical thicknesses and can have any number of functionalities. The second layer of IC dies may be flip-chip C4 attached to a substrate. A single carrier process with no RDL or BEOL processing is provided. The second layer of ICs can be designed and manufactured to serve a variety of functions that are optimal for their location within the disaggregated die module.

The architectures described herein may be assembled and/or fabricated with one or more of the features or attributes provided in accordance with various embodiments. A number of different assembly and/or fabrication methods may be practiced to enable the formation of disaggregated package substrate structures which reduce cost and increase design flexibility during processing, according to one or more of the features or attributes described herein.

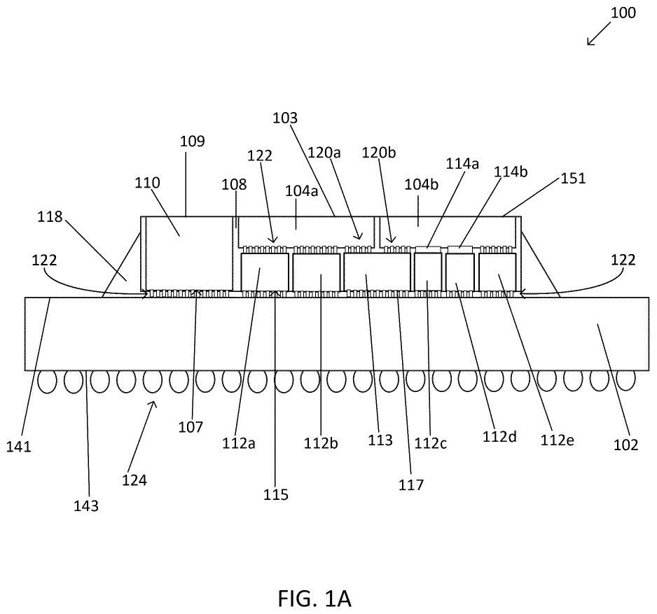

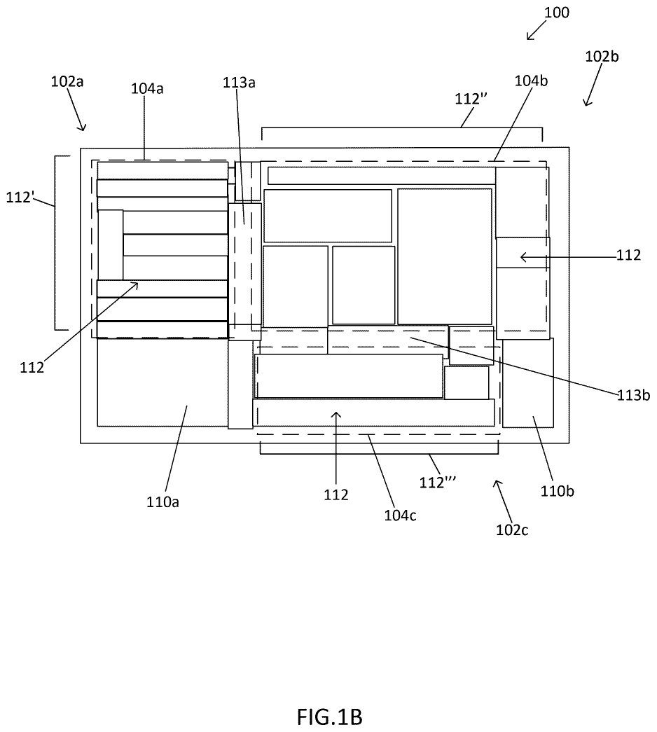

FIGS. 1A-1B illustrate embodiments of a disaggregated package structure comprising a set of first functional IC dies 112 directly coupled to a substrate 102, wherein the first IC dies 112 are directly attached to a set of second IC dies 104. In an embodiment, the set of first IC dies 112 may comprise silicon chiplets. The embodiments herein eliminate the need for wafer level processing of BEOL or RDL in substrate areas where it is not used and provides opportunities to add functional specific IC die vertically only where needed. The package structures may be formed utilizing standard IC processing techniques. The methods of fabrication described herein create improved device performance in advanced 2.5D and 3D packaging.

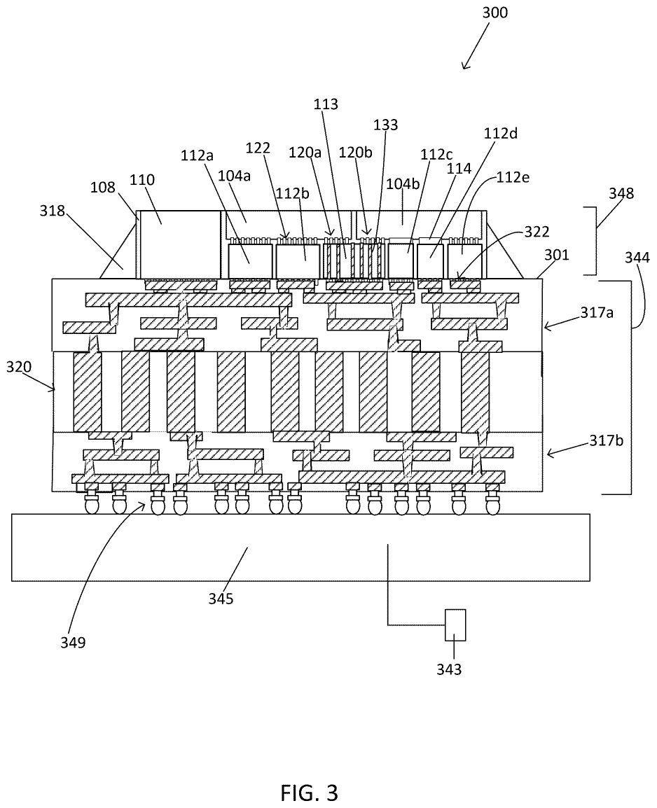

FIG. 1A is a cross-sectional view of a portion of disaggregated package structure 100 according to an embodiment. In an embodiment, the disaggregated package structure 100 depicts a substrate 102, which may comprise a ball grid array (BGA) substrate 102. In an embodiment, the substrate 102 may comprise a dielectric material with conductive traces dispersed within the dielectric material according to the particular design requirements of the embodiment, as depicted in FIG. 3 for example. In an embodiment, the substrate 102 may comprise an organic material, or it may comprise a layer of glass in an embodiment. The substrate 102 may comprise a first side 141 and a second side 143.

A set of two or more first IC dies 112 may be directly on the first side 141 of the substrate 102. As shown in the present embodiment, the set of first IC dies 112 may comprise first IC dies 112a-112e, however, any number or configuration of the set of first IC dies 112 may be directly on the first side 141 of the substrate 102. Conductive structures 122 may comprise conductive bumps or may be any other type of electrical connection in addition to or instead of the bumps shown (e.g., balls, pins, pads, wire bonding, etc., and may directly couple the two or more first IC dies 112 to the first side 141 of the substrate 102.

The set of first IC dies 112 may comprise any number of functionalities of IC dies 112. The set of first IC dies 112 may be designed and manufactured to serve a variety of functions that are optimal for their location within the disaggregated die module 100. The set of first IC dies 112 may be manufactured separately from a wafer/panel processing of the second IC dies 104. In an embodiment, the set of first IC dies 112 can be designed to be singulated to a variety of sizes from a single reticle design. In an embodiment, any of the set of first IC dies 112a-112e may comprise one or more functionalities such as a vertical interconnect IC die which may include through mold vias (TMVs) for signal or power delivery.

Another functionality of the set of first IC dies 112a-112e may include an active die comprising silicon processing for input/output (I/O) interface capabilities such as a universal chiplet interconnect express (UCIe) IC die, or a power management IC (PMIC), or a memory die. Another functionality of the set of first dies 112a-112e may include integrated passive devices such as capacitive, inductive or resistive device elements for use with a power delivery network. Another functionality of the set of first IC dies 112a-112e may include a solid metal IC die, comprising such conductive materials as copper, aluminum or alloys thereof for use with interconnect of a specific power or ground net, or for thermal or heat transfer IC dies for example.

In an embodiment, the set of first IC dies 112a-112e may be coupled to a set of second IC dies 104a 104b. The set of second IC dies 104 may comprise two or more IC dies, such as memory or logic IC dies for example. Each of the two or more second IC dies 104 may be electrically and mechanically coupled to a bridge die 113. In an embodiment, the bridge die 113 may comprise an organic interconnect bridge. In an embodiment, the bridge die 113 may comprise redistribution interconnect structures. In an embodiment, the bridge die 113 may comprise a silicon interconnect bridge that provides electrical connections between the second IC dies 104a, 104b. In an embodiment, the bridge die 113 may comprise a high density die-to-die interconnect structure with or without vertical through silicon vias (TSVs) to include power delivery or signal interconnect to the substrate 102. In an embodiment, the second IC die 104a may comprise a second IC die 104a that may be coupled to the bridge die 113 with bridge interconnect structures 120a, and the second IC die 104b may comprise a third IC die 104b that is coupled to the bridge die 113 with bridge interconnect structures 120b.

In an embodiment, the bridge interconnect structures 120a, 120b may comprise conductive bumps, or may be any other type of electrical connection in addition to or instead of the bumps shown (e.g., balls, pins, pads, wire bonding, etc. In an embodiment, the second IC die 104a and the third IC die 104b may comprise non-bridge conductive structures 122 which are adjacent to the bridge conductive structures 120a, 120b, wherein the non-bridge conductive structures 122 and are not coupled to the bridge die 113. In an embodiment, a diameter of the bridge interconnect structures 120a, 120b, may be the same as a diameter of the non-bridge conductive structures 122, or the diameter of the bridge interconnect structures 120a, 120b, may be different than the diameter of the non-bridge conductive structures 122.

In an embodiment, the non-bridge conductive structures 122 on the second IC die 104a and on the third IC die 104b may be directly coupled to at least one of the two or more first IC dies 112a-112e. In an embodiment, a mold material 108 may be between each of the two or more first IC dies 112a-112e and is between each of the second IC dies 104a, 104b. The mold material 108 may comprise an epoxy material in an embodiment and may be on a dummy die 110, which may be adjacent to the first IC dies 112a-112e and the second IC dies 104a, 104b, where the dummy die 110 may be directly on the substrate 102.

In an embodiment, the dummy die 110 may comprise dummy silicon blocks with a low coefficient of thermal expansion (CTE) filler material to improve mechanical performance and reliability of the disaggregated package structure/module 100. An underfill material 118 may be on the sides of the dummy die 110 and may surround conductive bumps 122. In an embodiment, first IC dies 112c, 12d may comprise passive ICs and may be coupled to the second IC die 104b with solder interconnects 114a, 114b. In an embodiment, solder bumps 124 may be on a second side 143 of the substrate 102. In an embodiment, a top surface 109 of the dummy die 110 may be coplanar with top surfaces 151 of the second IC dies 104a, 104b. Bottom surfaces 107 of the dummy die 110 may be coplanar with bottom surfaces 115, 117 of the first IC dies 112a-112e and the bridge die 113 respectively.

In FIG. 1B, a top view of a disaggregated IC package structure 100 is depicted, according to an embodiment. A plurality of first IC dies 112 may be on the substrate 102. In an embodiment, a first plurality 112′ of first IC dies 112 may be in a first portion of the substrate 102a, wherein a first top IC 104a may be attached and over the first plurality 112′ of first IC dies 112. The first plurality 112′ may comprise any number and configuration of first IC dies 112 according to the particular application.

In an embodiment, a second plurality 112″ of first IC dies 112 may be in a second portion 102b of the substrate 102, wherein a second top IC 104b may be attached and over the second plurality 112″ of first IC dies 112. The first and second top IC dies 104a, 104b may be coupled to each other by a bridge die 113a. The second plurality 112″ of IC dies may comprise any number and configuration of first IC dies 112. In an embodiment, a third plurality 112″′ of first IC dies 112 may be in a third portion 102c of the substrate 102, wherein a third top IC 104c may be attached and over the third plurality 112″ of first IC dies 112. The second and third top IC dies 104b, 104bc may be coupled to each other by a bridge die 113b. A first dummy die 110a and a second dummy die 110b may be in peripheral portions of the substrate 102 and may be adjacent the top IC die 104a, 104b, 104c and adjacent to the first, second and third pluralities of the first IC dies 112.

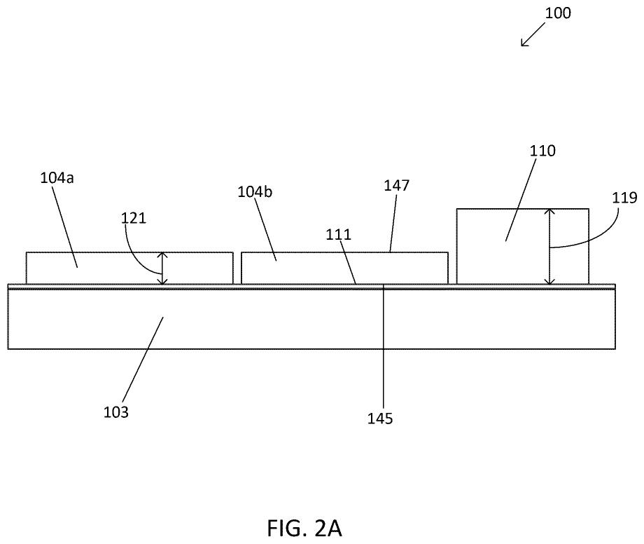

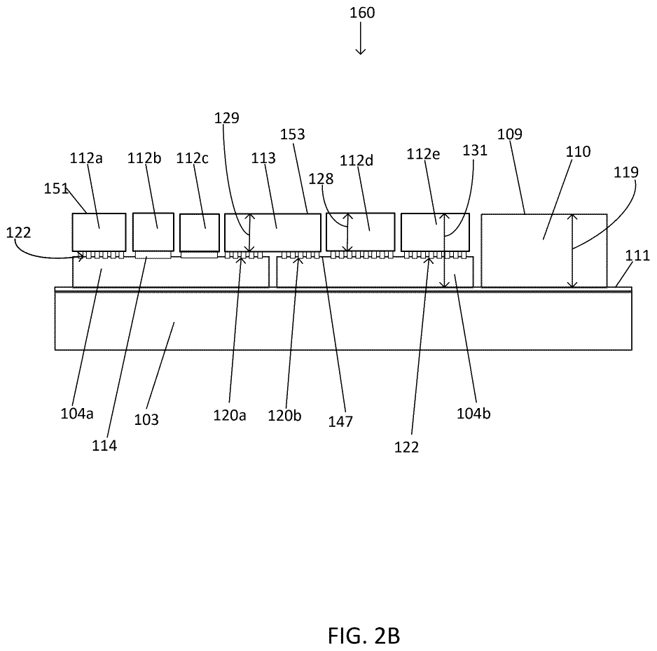

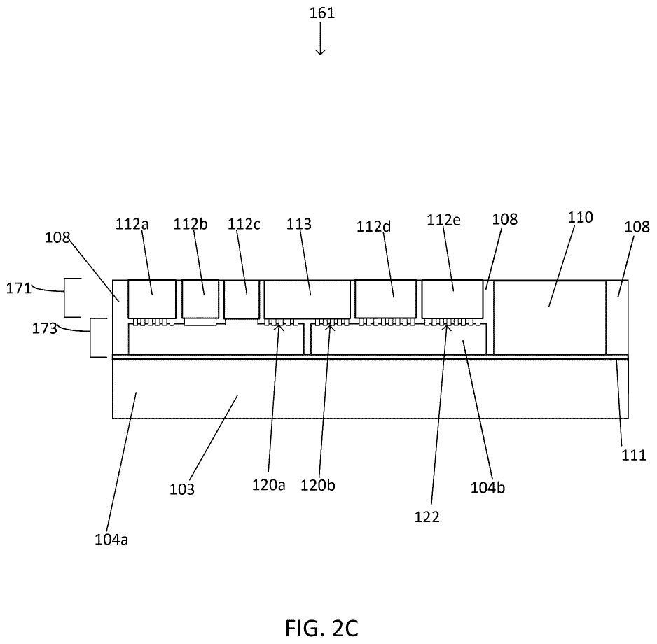

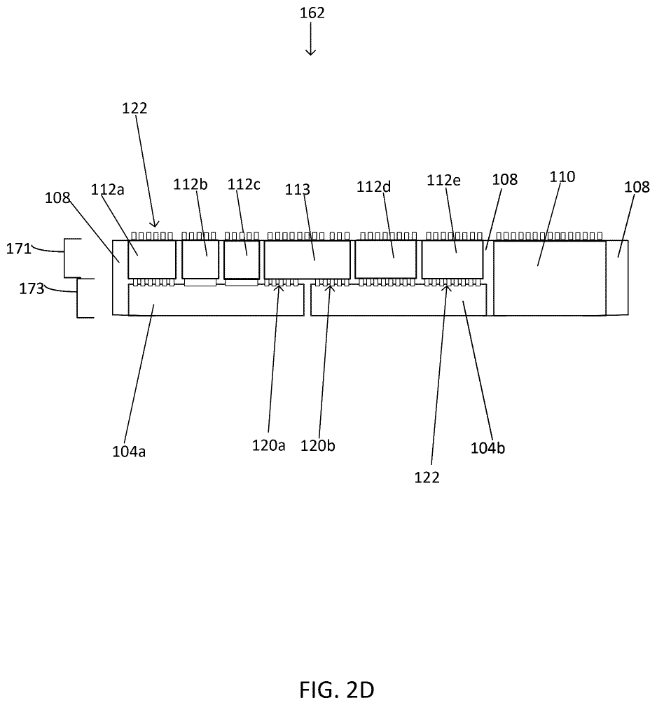

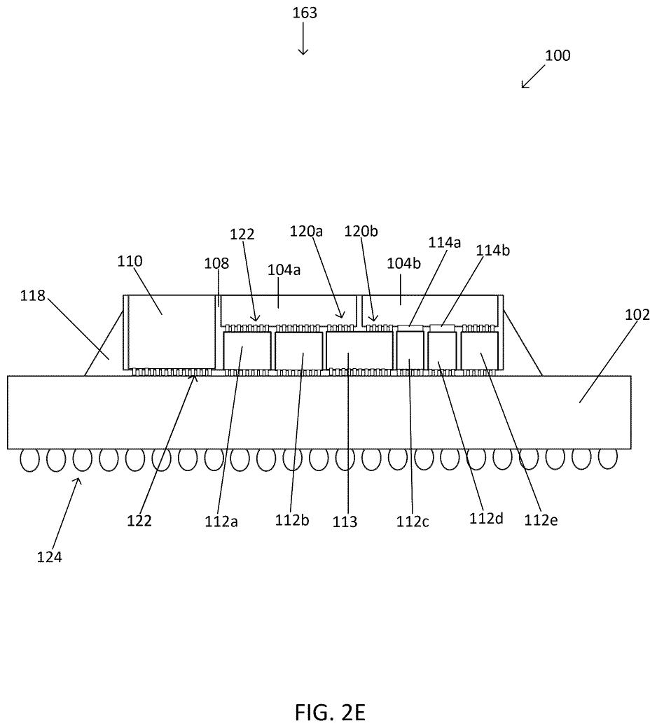

FIGS. 2A-2E depict methods of forming a disaggregated package structure according to embodiments, such as those depicted in FIGS. 1A-1B for example. FIG. 2A depicts a cross-sectional view of a portion of a disaggregated package structure 100 in an embodiment. The portion of the disaggregated package structure 100 may comprise a carrier substrate 103, which may comprise a temporary carrier or a host carrier in an embodiment. In an embodiment, the carrier substrate 103 may comprise a wafer or a panel carrier substrate.

Two or more first IC dies 104a, 104b may be on a carrier bond layer 111 which is on a surface of the carrier substrate 103. In an embodiment, the carrier bond layer 111 may comprise an adhesive material comprising a resin, a filler, a curing agent and/or a solvent. In an embodiment, the first IC dies 104a, 104b may be attached using any suitable die attach process, as are known in the art. The first IC dies 104a, 104b may comprise any suitable functionality, such as a CPU die or a memory die for example.

In an embodiment, one or more dummy dies 110, which may comprise a silicon material, may be attached to the bond layer 111 of the carrier substrate 103 adjacent to the first IC dies 104, 104b. In an embodiment, the one or more dummy dies 110 may comprise a thickness 119 which is greater than a thickness of the two first IC dies 104a, 104b depicted in FIG. 2A.

In an embodiment, the two first IC dies 104a, 104b comprise the same thickness 121 as each other. In an embodiment, the disaggregated package structure 100 comprises a reconstituted wafer with two first IC dies 104a, 104b and an adjacent dummy die 110 attached thereon. In an embodiment, the first IC dies 104a, 104b comprise a first side 145 and a second side 147, wherein the first side 145 is attached onto the carrier substrate 103. Any number of first IC dies 104 may be attached onto the carrier, according to particular design requirements.

FIG. 2B depicts a process 160 wherein a set of second IC dies 112 are attached onto the second sides 147 of the first IC dies 104a, 104ba. In an embodiment, the set of second IC dies 112, which are depicted in the figure as second IC dies 112a-12e, may be attached to the second sides 147 of the first IC dies 104a, 104b by conductive bumps 122, such as C4 bumps in an embodiment. The conductive bumps 122 may comprise micro-bumps in another embodiment. The conductive bumps 122 may be attached to the first dies 104a, 104b by utilizing the attachment process 160, which may comprise a mass reflow process or a thermal compression bonding (TCB) process. The set of second IC dies 112 may comprise any suitable functionalities, such as a memory IC, a power/ground IC, a passive IC, a PCMIA IC, a PCexpress IC, etc. The second IC dies 112 can be efficiently manufactured separately from the wafer/panel processing of the first IC dies 104a, 104b. In an embodiment, the second IC dies 112 can be designed to be singulated to a variety of sizes from a single reticle design to improve design flexibility.

Alternatively the process 160 may comprise attaching lower pitch (or thermal/power copper) second IC dies 112 to the first IC dies 104a, 104b by using a surface mount process. Subsequent to the attachment of the set of second IC dies 112a-112e, a single layer of second IC dies 112a-112e is formed on the first IC dies 104a, 104b which have substantially the same thickness 128 as each other and as a thickness 129 of a bridge die 113. In an embodiment, a combined thickness 131 of an individual one of the first IC die 104 and an individual one of the second IC die 112 may be substantially equal to the thickness 119 of the dummy die 110. In an embodiment, top sides 151 of the second IC dies 112 may be coplanar with top sides 109 of the dummy die 110 and may be coplanar with top sides 153 of the bridge die 113.

The bridge die 113 may be attached to the second sides 147 of a portion of two adjacent first IC dies 104, such as between the first IC die 104a and the adjacent first IC die 104b. The bridge die, which may comprise an organic interconnect bridge die in an embodiment, may be attached to the first IC dies 104a, 104b with bridge die interconnect structures 120a, 120b, which may comprise bridge die bumps 120a, 120b. In an embodiment, second IC dies 112b, 112c may be attached to the first IC dies 104a, 104b with a solder material 114.

FIG. 2C depicts a process 161 comprising an overmold process. In an embodiment, a mold material 108, such as an epoxy material for example, is formed between the second IC dies 112 and the bridge die 113 as well as on portions of the first IC dies 104. The mold material 108 fills any gaps between a second layer of IC dies 171 comprising the second IC dies 112, and a first layer of IC dies 173 comprising the first IC dies 104. In an embodiment, once the mold material 108 is placed between the IC dies in both layers 171,173 the mold material 108 may be cured and then may undergo a grinding process 162 to expose conductive structures 122 on the first layer 171 of second IC dies 112 and dummy die 110. (FIG. 2D). In an embodiment, there is no RDL layer between the first layer 171 and the second layer 173. The carrier 103 may be removed from the disaggregated module 100 and then the module/unit 100 may be singulated from the panel/carrier. In an embodiment, the bumps 122 on the second dies 112 may be formed while on the carrier substrate 103 or may be plated on a panel level in some embodiments, and the module 100 may then be removed from the temporary carrier 103.

Singulated modules 100 are then flip-chip C4 attached to a BGA substrate 102 and underfilled with an underfill material 118 as shown in FIG. 2E utilizing process 163. The embodiments herein provide a single carrier process with no RDL or BEOL processing. Die attach, overmold and bumping processes are employed which provide a simplified, less expensive process to form the disaggregated module 100.

FIG. 3 depicts an IC package structure 300, such as a disaggregated package structure 300, which may be similar to the portions of the package structures depicted in FIGS. 1A-1B for example. The disaggregated package structure 300 comprises first IC dies 112, (shown as 112a-112e) directly coupled to second IC dies 104 (shown as 104a-104b) through conductive structures 122. In an embodiment, the first IC dies 112 may comprise any functionality, such as a passive IC die 112a, such as a silicon IC die for example, a vertical TMV IC die 112b for power/ground IC dies, a power IC die 112c, a ground IC die 112d, or an active I/O IC die 112e. The first IC dies 112 may be located in any position on a first surface 301 of package substrate 344.

In an embodiment, first IC dies 112c, 112d of the module 348 may be directly coupled to the first IC die 104b by solder interconnects 114. The first IC dies 112a-112e may comprise any suitable functionality such as a memory IC, or a CPU IC die for example. A bridge structure 113 may be directly coupled to the first IC die 104a and the second IC die 104b through bridge interconnect structures 120a, 120b respectively. In an embodiment, the bridge die may comprise a plurality of through silicon vias 133. In an embodiment, a mold compound 108 may at least partially surround the first and the second IC dies 112, 104 and may additionally surround a dummy die 110. The dummy die 110 is adjacent to the first and second IC dies, 112, 104. The dummy die 110 may comprise silicon for example. An underfill material 318 may be on the mold material 108 and may surround the first and second IC dies, 112, 104.

The substrate 344 may comprise a core 320 with a first buildup layer 317a and a second buildup layer 317b on either side of the core 320. Buildup layers 317a, 317b may comprise a multiple-layer stack of overlaid sheets of laminated film (e.g., buildup film). Buildup layers 317a, 317b materials may include composite epoxies, liquid crystalline polymers and polyimides. Other suitable materials may be employed. In some embodiments, buildup layers 317a, 317b are a monolithic block rather than laminated film. Suitable organic or inorganic materials may be employed. Buildup layers 317a, 317b may include such materials as FR4 (e.g., epoxy-based laminate), bismaleimide-triaxine, polyimide, silicon, or epoxy resin. buildup layers 317a, 317b may comprise organic buildup film or any other dielectric material suitable for electrical packaging.

The buildup layers 317a, 317b may form a structure with a desired thickness. In an embodiment, the buildup layers 317a, 317b may comprise electrically conductive features (e.g., pads, traces, vias, etc.) that are fabricated in conjunction with the formation of the buildup layers 317a, 317b. The conductive traces located throughout which may couple another substrate or die and may comprise copper or copper alloys in an embodiment.

The core 320 may comprise any suitable materials such as glass or dielectric materials in an embodiment. In an embodiment, the first and second IC dies 112, 104 may comprise chiplet structures which may comprise components of a system on a chip (SOC) structure that may be coupled to the core 320. Any number of die/devices may be coupled to the package substrate 344. The package substrate 344 and the device(s) 112, 104 may be coupled to a board 345, such as a printed circuit board, in an embodiment. The board 345 may be coupled to the package substrate 344 through solder structures 349 in an embodiment.

A power supply 343, which may comprise any suitable power supply as known in the art, may be coupled to dies 104, 112 via IC package substrate 344, in an embodiment. Solder interconnect structures 322 may couple the dies 112, 104 to the substrate 344. The circuit board 345 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board. In other examples, the circuit board may be a non-PCB substrate.

In some examples, the IC package 300 structure includes additional passive components, such as surface-mount resistors, capacitors, and/or inductors surfaces of the package substrate 344.

Discussion now turns to operations for assembling and/or fabricating the discussed structures.

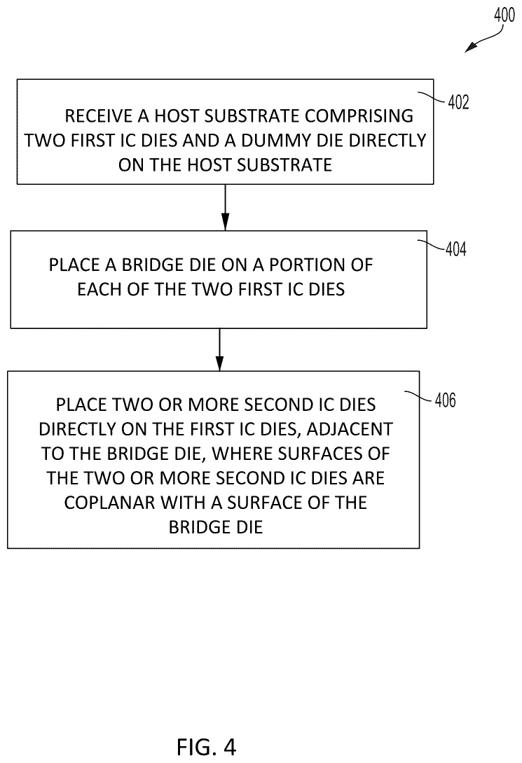

FIG. 4 is a flow chart of a process 400 of fabricating package structures, such as a disaggregated package structure comprising functional IC blocks directly attached to top dies. For example, process 400 may be used to fabricate any of the microelectronic IC package structures of FIGS. 1A-1B, for example.

As set forth in block 402, a host substrate may be received comprising two first IC dies and a dummy die directly on the host substrate. The host substrate comprises a first side and a second side, opposite the first side. The host substrate may comprise a carrier substrate. In an embodiment, the two or more first IC dies may comprise a first top die and a second top die. In an embodiment, the two first IC dies may comprise a silicon chip or chiplets. In an embodiment, the two first dies may comprise a central processing unit (CPU) or a field programmable gate array (FPGA) die, for example or may comprise any suitable logic die for a particular application.

The two first IC dies may be attached utilizing any suitable die attach process, as are known in the art. The two first IC dies can provide any suitable type of functionality (e.g., data processing, memory storage, etc.). Each of first sides of the two first IC dies is electrically and mechanically coupled directly to the host substrate via corresponding arrays of conductive interconnects. In an embodiment, the conductive interconnects may comprise conductive bumps. However, the interconnects may be any other type of electrical connection in addition to or instead of the bumps shown (e.g., balls, pins, pads, wire bonding, etc.).

In an embodiment, one or more dummy dies may be placed adjacent to the two first IC dies, directly on the host substrate. In an embodiment, any number of dummy dies may be placed adjacent to the first IC dies on the substrate. In an embodiment, the dummy dies may comprise silicon blocks with a low coefficient of thermal expansion filler material to improve mechanical performance of the disaggregated package substrate. The first sides of the dummy dies may be placed on areas on the host substrate which do not have first IC dies. In an embodiment, the first IC dies and the dummy dies may be attached onto a wafer or a panel carrier to create a reconstituted wafer (or panel) with first IC die pads or bumps exposed.

As set forth in step 404, a bridge die may be placed on a portion of each of the two first IC dies. A first side of the bridge die may be placed on second sides of portions of the two first IC dies. The bridge die may comprise an embedded interconnect bridge die. In an embodiment, the bridge die may comprise high density die-to-die interconnect structures with or without vertical through silicon vias (TSVs) to include power delivery or signal interconnect to the substrate. The bridge die may be coupled to the two first IC dies with conductive bridge bumps. In an embodiment, the conductive bridge bumps are bumps on the bridge die through which electrical signals pass between the bridge die and the first IC dies. In an embodiment, the first IC dies may comprise core bumps that are adjacent to the bridge bumps, wherein core bumps may be larger than bridge bumps.

At step 406, first sides of two or more second IC dies are placed directly on second sides of the first IC dies, adjacent to the bridge die. In an embodiment, the two or more second IC dies may be attached to the first IC dies with C4 or micro bump die attach process with mass reflow or thermal-compression bonding (TCB). Alternately lower pitch (or thermal/power copper) second IC dies may be attached with a surface mount process. In an embodiment, second sides of the two or more second IC dies are coplanar with a second side of the bridge die. In an embodiment, a second side of the dummy die is coplanar with second sides of the of two or more second IC dies. In an embodiment, the two or more second IC dies may comprise different functionalities/process flows, such as BEOL, RDL, Cu block, TMV etc. In an embodiment, the two or more second IC dies may be placed adjacent to each other in an intermediate layer between the first IC dies and the substrate.

In an embodiment, the two or more second IC dies may comprise, a vertical interconnect IC die with through mold vias for signal or power delivery, an active die with full silicon process having functionality for input/output (I/O) interface such as UCIe, PMIC, or Memory IC. In an embodiment, the two or more second IC dies may comprise an integrated passive device with capacitive or inductive elements for a power delivery network. In another embodiment, the two or more second IC dies may comprise a solid metal block comprising such conductive materials as copper, aluminum, or their alloy, wherein the two or more second IC dies may be used for interconnect for specific power or ground network, or for thermal or heat transfer. The two or more second IC dies may be placed on the host substrate using a pick and place process in an embodiment.

In an embodiment, surfaces of the dummy die and the two or more second IC dies may be placed onto a substrate, such as a ball grid array substrate and the host substrate may be removed, In an embodiment, the substrate may comprise a core, such as a silicon or a glass core. In other embodiments, the substrate may be a coreless substrate. In some embodiments, the substrate may comprise organic material. In some embodiments, the substrate may comprise build-up layers on a first and a second side of a core.

In an embodiment, the substrate may include multiple metal layers separated from one another by layers of dielectric material and interconnected by electrically conductive vias. In some examples, the substrate may be formed of an epoxy resin, a fiberglass-reinforced epoxy resin, an epoxy resin with inorganic fillers, a ceramic material, or a polymer material such as polyimide. In some examples, the substrate may be formed of alternate rigid or flexible materials that may include the same materials described above for use in a semiconductor substrate, such as silicon, germanium, and other group III-V and group IV materials.

The substrate may include metal interconnects and vias, including but not limited to through-silicon vias (TSVs. The substrate may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices.

The embodiments herein enable a single layer of multiple function IC dies with identical thicknesses. The embodiments herein utilize an intermediate layer of disaggregated IC dies of different functionalities that are directly attached to ta first layer of IC dies. The package structures described herein prevent the need for wafer level processing of silicon back end of line (BEOL) or redistribution layer (RDL) in areas that are not used on the substrate and provide an opportunity to add use-specific IC dies vertically only where needed.

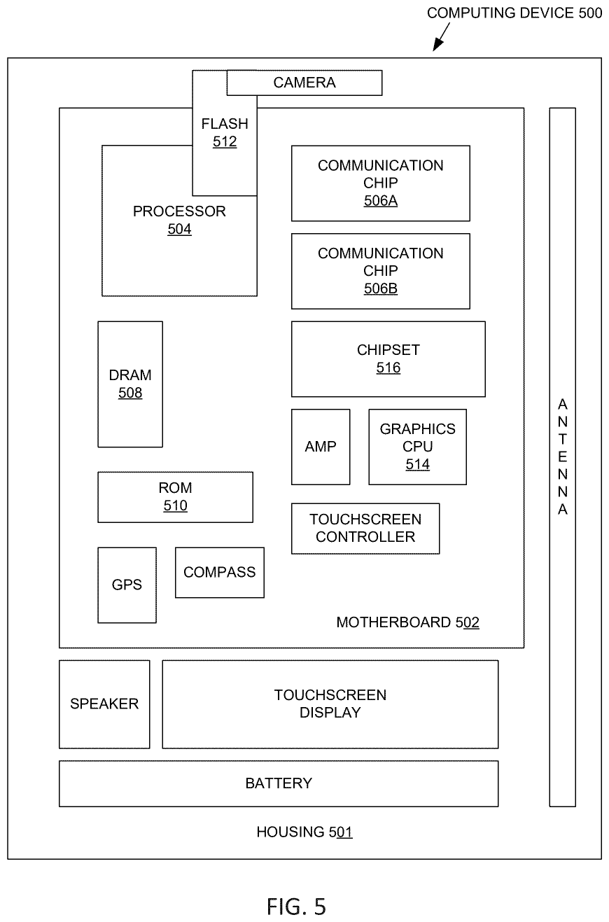

FIG. 5 illustrates an electronic or computing device 500 in accordance with one or more implementations of the present description. The computing device 500 may include a housing 501 having a board 502 disposed therein. The computing device 500 may include a number of integrated circuit components, including but not limited to a processor 504, at least one communication chip 506A, 506B, volatile memory 508 (e.g., DRAM), non-volatile memory 510 (e.g., ROM), flash memory 512, a graphics processor or CPU 514, a digital signal processor (not shown), a crypto processor (not shown), a chipset 516, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 502. In some implementations, at least one of the integrated circuit components may be a part of the processor 504.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a substrate having two or more functional IC dies directly on the substrate. A dummy die is adjacent to the two or more IC dies where top dies are directly on at least one of the two or more functional IC dies.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-5. The subject matter may be applied to other integrated circuit devices and assembly applications, as well as any appropriate electronic application, as will be understood to those skilled in the art.

The following examples pertain to further embodiments and specifics wherein the examples may be used anywhere in one or more embodiments, wherein a first example is an apparatus comprising two or more first integrated circuit (IC) dies directly on and electrically coupled to a substrate a bridge die adjacent to the two or more first IC dies and directly on the substrate. A second IC die directly on the bridge die and on at least one of the two or more first IC dies and a third IC die directly on the bridge die, adjacent to the second IC die, wherein a mold material at least partially surrounds the two or more first IC dies and the second and third IC dies.

In second examples, the first example further comprises wherein the two or more first IC dies comprise one or more of a power module integrated circuit die, a memory die, a power or ground die, a vertical through mold die, a solid metal die, or a passive die.

In third examples, the second example further comprises wherein the passive die comprises one or more of a capacitor die, a resistor die, or an inductor die.

In fourth examples, wherein any of examples 1-3 further comprise wherein a first portion of the third IC die is on the bridge die, and a second portion of the third IC die is on at least one of the two or more first IC dies.

In fifth examples, wherein any of examples 1-4 further comprises wherein the bridge die comprises an organic interconnect bridge die, wherein a surface of the organic interconnect bridge die is coplanar with surfaces of the two or more first IC dies.

In sixth examples, wherein any of examples 1-5 further comprises wherein a dummy die is on the substrate adjacent to the second IC die and the third IC die and wherein a surface of the dummy die is coplanar with a surface of the second IC die and with a surface the third IC die.

In seventh examples, wherein any of examples 1-6 further comprises wherein the mold material comprises an epoxy material.

In eighth examples, wherein any of examples 1-7 further comprises wherein the two or more first IC dies are located in an intermediate layer between the second IC die and the substrate.

In ninth examples, wherein any of examples 1-8 further comprise wherein the two or more first IC dies comprise a first layer, and the second IC die adjacent to the third IC die comprise a second layer, wherein the second layer is over the first layer.

In tenth examples, wherein any of examples 1-9 further comprises wherein the substrate comprises a first portion and a second portion, the first portion comprising the two or more first IC dies directly attached to the substrate, and the second portion comprising one or more dummy dies directly attached to the substrate.

In eleventh examples, wherein example 10 further comprises wherein the one or more dummy dies are in a peripheral region of the substrate.

Example 12 is an apparatus comprising a first side and a second side, a first plurality of first IC dies each separated by a distance directly on the first side of the substrate, wherein a plurality of solder connections is on the second side of the substrate. A bridge die is directly on the first side of the substrate, the bridge die between the first plurality of first IC dies and a second plurality of first IC dies, and a portion of a second IC die directly on the bridge die, and a portion of a third IC die directly on the bridge die, adjacent to the second IC die, wherein a mold material is between the first plurality of first IC dies and spans the distance.

In thirteenth examples, wherein examples 12 further comprises wherein a dummy die is adjacent the first IC die or the second IC die, wherein a thickness of the dummy die is substantially the same as a combined thickness of the first IC die and the second IC die.

In fourteenth examples, wherein any of examples 12-13 further comprises wherein the bridge die comprises a plurality of through silicon vias.

In fifteenth examples, wherein any of examples 12-14 further comprise wherein the mold material is between the second plurality of first IC dies and spans the distance.

In sixteenth examples, wherein any of examples 12-15 further comprise wherein a fourth IC die is adjacent the second IC die or the third IC die, wherein the fourth IC die is over a third plurality of first IC dies.

Example 17 is a method comprising receiving a host substrate comprising a first IC die adjacent to a second IC die on a surface of the host substrate, wherein a dummy die is adjacent the first IC die and the second IC die, placing a bridge die on a first portion of the first IC die and on a first portion of the second IC die, placing a first plurality of third IC dies directly on a second portion of the first IC die, and placing a second plurality of the third IC dies on a second portion of the second IC die, wherein the bridge die is between the first plurality and the second plurality and wherein surfaces of the first plurality and the second plurality of third IC dies are coplanar with a surface of the bridge die.

In eighteenth examples, wherein example 17 further comprises placing the surfaces of the first plurality and the second plurality of third IC dies and the surface of the bridge die on a substrate.

In nineteenth examples, wherein example 18 further comprises wherein a surface of the dummy die is coplanar with the surfaces of the first plurality and the second plurality of third IC dies.

In twentieth examples, wherein any of example 17-19 placing the two or more third IC dies comprises directly attaching one or more of a power management IC die, a power IC die, a ground IC die, a vertical through mold via IC die, or a passive IC die.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
two or more first integrated circuit (IC) dies directly on and electrically coupled to a substrate;
a bridge die adjacent to the two or more first IC dies and directly on the substrate;
a second IC die directly on the bridge die and on at least one of the two or more first IC dies; and
a third IC die directly on the bridge die, adjacent to the second IC die, wherein a mold material at least partially surrounds the two or more first IC dies and the second and third IC dies.

2. The apparatus of claim 1, wherein the two or more first IC dies comprise one or more of a power module integrated circuit die, a memory die, a power or ground die, a vertical through mold die, a solid metal die, or a passive die.

3. The apparatus of claim 2, wherein the passive die comprises one or more of a capacitor die, a resistor die, or an inductor die.

4. The apparatus of claim 1, wherein a first portion of the third IC die is on the bridge die, and a second portion of the third IC die is on at least one of the two or more first IC dies.

5. The apparatus of claim 1, wherein the bridge die comprises an organic interconnect bridge die, wherein a surface of the organic interconnect bridge die is coplanar with surfaces of the two or more first IC dies.

6. The apparatus of claim 1, wherein a dummy die is on the substrate adjacent to the second IC die and the third IC die and wherein a surface of the dummy die is coplanar with a surface of the second IC die and with a surface the third IC die.

7. The apparatus of claim 1, wherein the mold material comprises an epoxy material.

8. The apparatus of claim 1, wherein the two or more first IC dies are located in an intermediate layer between the second IC die and the substrate.

9. The apparatus of claim 1, wherein the two or more first IC dies comprise a first layer, and the second IC die adjacent to the third IC die comprise a second layer, wherein the second layer is over the first layer.

10. The apparatus of claim 1, wherein the substrate comprises a first portion and a second portion, the first portion comprising the two or more first IC dies directly attached to the substrate, and the second portion comprising one or more dummy dies directly attached to the substrate.

11. The apparatus of claim 10, wherein the one or more dummy dies are in a peripheral region of the substrate.

12. An apparatus, comprising:
a substrate comprising a first side and a second side;
a first plurality of first IC dies each separated by a distance directly on the first side of the substrate, wherein a plurality of solder connections is on the second side of the substrate;
a bridge die directly on the first side of the substrate, the bridge die between the first plurality of first IC dies and a second plurality of first IC dies; and
a portion of a second IC die directly on the bridge die, and a portion of a third IC die directly on the bridge die, adjacent to the second IC die, wherein a mold material is between the first plurality of first IC dies and spans the distance.

13. The apparatus of claim 12, wherein a dummy die is adjacent the first IC die or the second IC die, wherein a thickness of the dummy die is substantially the same as a combined thickness of the first IC die and the second IC die.

14. The apparatus of claim 12, wherein the bridge die comprises a plurality of through silicon vias.

15. The apparatus of claim 12, wherein the mold material is between the second plurality of first IC dies and spans the distance.

16. The apparatus of claim 12, further comprising wherein a fourth IC die is adjacent the second IC die or the third IC die, wherein the fourth IC die is over a third plurality of first IC dies.

17. A method, comprising:
receiving a host substrate comprising a first IC die adjacent to a second IC die on a surface of the host substrate, wherein a dummy die is adjacent the first IC die and the second IC die;
placing a bridge die on a first portion of the first IC die and on a first portion of the second IC die;
placing a first plurality of third IC dies directly on a second portion of the first IC die;
and placing a second plurality of the third IC dies on a second portion of the second IC die, wherein the bridge die is between the first plurality and the second plurality and wherein surfaces of the first plurality and the second plurality of third IC dies are coplanar with a surface of the bridge die.

18. The method of claim 17, further comprising placing the surfaces of the first plurality and the second plurality of third IC dies and the surface of the bridge die on a substrate.

19. The method of claim 18, wherein a surface of the dummy die is coplanar with the surfaces of the first plurality and the second plurality of third IC dies.

20. The method of claim 17, wherein placing the two or more third IC dies comprises directly attaching one or more of a power management IC die, a power IC die, a ground IC die, a vertical through mold via IC die, or a passive IC die.
